(19) United States
(12) Patent Application Publication
(10) Pub. No.: US 2026/0321444 A1
(43) Pub. Date: Oct. 15, 2026

(54) BURNABLE POISON COATING AND PREPARATION METHOD THEREFOR, AND NUCLEAR FUEL ELEMENT

(71) Applicants: SHANGHAI NUCLEAR ENGINEERING RESEARCH & DESIGN INSTITUTE CO., LTD., Shanghai (CN); SHANGHAI INSTITUTE OF CERAMICS, CHINESE ACADEMY OF SCIENCES, Shanghai (CN)

(72) Inventors: Xiangyang Chen, Shanghai (CN); Yan You, Shanghai (CN); Junqiang Lu, Shanghai (CN); Man Zhang, Shanghai (CN); Zhaoquan Zhang, Shanghai (CN); Cong Li, Shanghai (CN); Xiaojiao Wang, Shanghai (CN); Wugang Fan, Shanghai (CN); Xiangyu Wei, Shanghai (CN)

(21) Appl. No.: 19/108,482

(22) PCT Filed: Sep. 5, 2023
(86) PCT No.: PCT/CN2023/116956

§ 371 Date: Mar. 4, 2025

(30) Foreign Application Priority Data
Sep. 5, 2022 (CN) 202211077822.0

(51) Int. Cl. G21C 3/20; G21C 3/62

(52) U.S. Cl. CPC G21C 3/20; G21C 3/623; G21C 3/626

(57) ABSTRACT

Provided is a burnable poison coating, which is made of at least one of CeB₆, SiB₆, and YB₆, and the density of the burnable poison coating is 70% to 97% of the theoretical density of the used material. The present invention further relates to a method for preparing the burnable poison coating, and a nuclear fuel element comprising a nuclear fuel pellet to which the coating is applied.

### TECHNICAL FIELD

The present invention relates to the field of nuclear fuel technology, and in particular to a burnable poison coating and a preparation method therefor, and a nuclear fuel element.

### BACKGROUND

In the initial stage of the first charging or the first refueling cycle of a pressurized water reactor, the initial residual reactivity of the core is relatively large, and chemical compensation poisons, burnable poisons or control rods are required to control the residual reactivity.

For burnable poisons, the main functions are embodied in two aspects: the first aspect is to obtain the maximum fuel utilization rate and reduce the fuel cycle cost, specifically, the ability of the burnable poison to absorb excess neutrons decreases steadily with the stable operation, so that the reactivity restricted by the burnable poison is gradually and finally fully released during the burnup process; the second aspect is to provide good power distribution control capability to achieve the best match between the consumption of burnable poisons and the fuel burnup in terms of rate and spatial relationship.

Some documents (C. E. Sanders, J. C. Wagner, Study of the effect of integral burnable absorbers for PWR burnup credit, 2002; M. O'Leary, M. L. Pitts, Effects of Burnable Absorbers on PWR Spent Nuclear Fuel, Office of Scientific & Technical Information Technical Reports, 2000; J. R. Cacciapouti, Axial Burnup Profile Database for Pressurized Water Reactors, 2000) have studied and analyzed burnable poison nuclides. Currently, the commonly used burnable poison nuclides are mainly ¹⁰B, ¹⁵⁷Gd and ¹⁶⁷Er. ¹⁵⁷Gd and ¹⁶⁷Er are mainly doped into nuclear fuels in the form of oxides, and the total poison residue at the end of life is stable at more than 4% of the initial toxicity. The consumption of element B decreases steadily and matches well with the fuel burnup, with almost no residual penalty effect. Since the consumption rate always decreases slowly, B element is widely used, and the burnable poison materials used in pressurized water reactors at home and abroad mainly include boron stainless steel, boron carbide-alumina, borosilicate glass and zirconium boride coatings.

Currently, there are two structural forms of commercial integral burnable poisons: (1) mixing the burnable poison absorber with the nuclear fuel powder and sintering them together to form a composite fuel pellet containing the burnable poison absorber, such as dispersing Gd₂O₃ or Er₂O₃ in UO₂ fuel and forming a sintered body; (2) applying a layer of burnable poison coating on the surface of the nuclear fuel pellet, such as applying ZrB₂ on the surface of the fuel pellet to form an integral fuel burnable poison. The ¹⁰B enrichment in the commercial ZrB₂ coating of the AP1000 series nuclear power model exceeds 50 wt %, and the enriched boric acid is used as raw material for production, which leads to a high manufacturing cost, while the adhesion between the coating and the substrate needs to be further improved. CN111573687A discloses a neutron absorber material with a high boron loading capacity and a higher neutron reactivity value, the neutron absorber material is a polyboron compound, the chemical formula of which is MBₓ, wherein x is not less than 6, the mass fraction of B is not less than 75%, and Mis an element with a thermal neutron absorption cross section not exceeding 1.5 barns and a mixture thereof such as Al, Mg, Si, Y. It does not propose to apply the above material to the surface of nuclear fuel pellets, nor does it verify whether a coating process on the surface of nuclear fuel pellets can be realized.

### SUMMARY

In order to solve the above problems, the present application provides a burnable poison coating and a preparation method therefor, and a nuclear fuel element, which realizes long-term reactivity control and negative temperature coefficient control for moderator while achieving a reactivity regulation function similar to that of a ZrB₂ coating. The requirement for the enrichment of ¹⁰B is reduced, and even the naturally abundant boric acid may be used for production, thereby reducing material costs.

A first aspect of the present application provides a burnable poison coating, wherein the burnable poison coating is made of at least one of CeB₆, SiB₆, and YB₆, and a relative density of the burnable poison coating is 70% to 97% of a theoretical density of the used material.

As an embodiment, the burnable poison coating has a thickness of 5 to 20 μm.

As an embodiment, the burnable poison coating has a ¹⁰B linear density of 0.02 to 0.1 mg/mm.

As an embodiment, a ¹⁰B enrichment in the burnable poison coating is 18.4 wt % to 30 wt %.

As an embodiment, an initial reactivity value of the burnable poison coating differs by no more than 200 pcm from that of a ZrB₂ coating with the same ¹⁰B linear density; or
a reactivity penalty at end of life of the burnable poison coating differs by no more than 30 pcm from that of the ZrB₂ coating with the same ¹⁰B linear density; or
after being subjected to 600° C. thermal shock test for at least 3 times, the burnable poison coating has a mass loss of less than 0.0006 g as measured by a tape peel test.

The present application further provides a method for preparing any one of the above burnable poison coatings, wherein the burnable poison coating is prepared by a magnetron sputtering process, and a specific operation process of the method includes: adopting a coating material composed of at least one of CeB₆, SiB₆, and YB₆, placing a fuel pellet at center of a bottom plate of a rotating sample holder in a sample chamber, and covering an upper surface of a sample with a metal sheet; and adjusting an Ar gas flow rate in the sample chamber into a range of 60 to 80 sccm, adjusting a vacuum degree in the sample chamber into a range of 0.6 to 0.8 Pa, maintaining a temperature in the sample chamber in a range of 200 to 300° C., coating the fuel pellet for 60 to 70 hours while maintaining a current of the coating material in a range of 120 to 150 mA after arcing of a magnetron, and raising the temperature in the sample chamber into a range of 400 to 420° C. which is then maintained for 1 to 1.2 h.

The present application further provides a nuclear fuel element, including a nuclear fuel pellet, wherein a surface of the nuclear fuel pellet is coated with any one of the above burnable poison coatings.

As an embodiment, a material of the nuclear fuel pellet is at least one of uranium dioxide, thorium dioxide, plutonium dioxide, uranium dioxide-gadolinium oxide, thorium dioxide-gadolinium oxide, plutonium dioxide-gadolinium oxide and mixtures thereof.

As an embodiment, the nuclear fuel element further includes a structural material (cladding material) for isolating the nuclear fuel pellet from a coolant and a sealing material (an end plug material) for blocking an opening of the structural material, wherein the structural material and the sealing material have thermal neutron microscopic absorption cross sections not exceeding 1.5 barns, and no apparent chemical reaction occurs with the nuclear fuel pellet and the coolant from room temperature to 800° C.

The beneficial effects of the present invention are as follows:
(1) The present invention provides a burnable poison coating applied to the surface of a nuclear fuel pellet, and the burnable poison coating is made of at least one of CeB₆, SiB₆, and YB₆. The B densities of CeB₆, SiB₆, and YB₆ are 1.52 g/cm³, 1.7 g/cm³, and 1.56 g/cm³, respectively, which are 30%, 45%, and 33% higher than that of ZrB₂ (1.17 g/cm³). With the close ¹⁰B linear density, relative density, and thickness of coating, the requirement for ¹⁰B enrichment can be significantly reduced. Since the price of boric acid used for preparing materials containing B increases exponentially with the enrichment of ¹⁰B, the use of the burnable poison coating according to the present invention can significantly reduce raw material costs. At the same time, the bonding strength between the coating and the substrate pellet is better than that of ZrB₂, which has higher reliability during service and is more conducive to core safety.
(2) The coating according to the present invention has good compatibility with the nuclear fuel pellet substrate at temperatures ranging from room temperature to 800° C., and no interface reaction between the coating and the fuel pellet is observed using a metallographic microscope.

### BRIEF DESCRIPTION OF THE DRAWINGS

In order to illustrate the technical solution of the embodiments of the present application more clearly, the accompanying drawing to be used in the embodiments of the present application will be briefly introduced below. Obviously, the accompanying drawings described below is only for illustrating the specific embodiments of the present application, and those skilled in the art can obtain other embodiments according to the following figures without making creative efforts.

FIG. 1 is a schematic diagram of a fuel element having a fuel pellet covered with a burnable poison coating according to the present invention.

FIG. 2 is an enlarged cross-sectional view along the A-A direction in FIG. 1.

FIG. 3 shows the nuclear characteristic curves (burnup curves) of four burnable poison coatings of SiB₆, YB₆, CeB₆, and ZrB₂ with the same ¹⁰B linear density, wherein ZrB₂ is used as a comparison. The reactivity value curves, which change with the burnup, of the three schemes of SiB₆, YB₆ and CeB₆ are basically the same as the curve of ZrB₂, so they overlap in the figure. That is, the initial reactivity value differs by no more than 200 pcm from that of the ZrB₂ coating with the same ¹⁰B linear density, and the reactivity penalty at the end of life differs by no more than 30 pcm from that of the ZrB₂ coating with the same ¹⁰B linear density.

FIG. 4 is a microstructure photograph of a cross section of a UO₂ pellet applied with the CeB₆ coating on the surface, and the thicknesses of the coating at three locations are measured and marked in each figure, wherein the average coating thickness is about 10 μm.

FIG. 5 is a grazing incident X-ray diffraction spectrum of a surface of a UO₂ pellet coated with the CeB₆ coating, wherein besides the diffraction peak of the UO₂ substrate, the rest are diffraction peaks of CeB₆.

FIG. 6 shows the tape peel test result of the UO₂ pellet coated with the CeB₆ coating and the UO₂ pellet coated with the ZrB₂ coating after 5 times of 600° C. thermal shock tests.

### REFERENCE NUMERALS

1—Upper end plug, 2—Spring, 3—Cladding, 4—Coated pellet, 41—Burnable poison coating, 5—Support block, 6—Support tube, 7—Lower end plug, 8—Nuclear fuel pellet, 9—Burnable poison coating, 10—Gap between coated pellet and cladding tube.

The accompanying drawings, which are incorporated in and form a part of the Specification, illustrate embodiments consistent with the present application and together with Specification, serve to explain the principles of the present application.

### DETAILED DESCRIPTION

In order to better understand the technical solutions of the present application, the embodiments of the present application will be described in detail below in conjunction with the accompanying drawings.

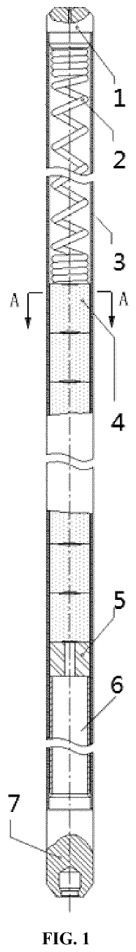

FIG. 1 is a schematic diagram of a fuel element having a fuel pellet covered with a burnable poison coating according to the present invention. FIG. 2 is an enlarged cross-sectional view along the A-A direction in FIG. 1.

As shown in FIGS. 1 and 2, the upper end plug 1 is used to seal the upper end of the cladding tube; the spring 2 is used for stress buffering; the cladding 3 is used to seal the fuel pellet to prevent leakage of the fission gas of the nuclear fuel pellet; the pellet 4 coated with a coating is used to provide a controllable chain neutron reaction; the support block 5 and the support tube 6 are respectively used to increase the distance between the fuel pellet and the core lower plate, increase the volume of the gas cavity of the fuel rod, reduce the irradiation damage of the core lower plate, and reduce the internal pressure of the fuel rod in the later stage of irradiation; the lower end plug 7 is used to seal the lower end of the cladding tube; the nuclear fuel pellet 8 provides a substrate pellet for coating; the burnable poison coating 9 is used to be applied on the surface of the fuel pellet to regulate the neutron reactivity; and the gap 10 between the coated pellet and the cladding tube provides a space for the irradiation swelling of the fuel pellet and the release of fission gas.

The main components of the burnable poison coating 9 include B and at least one of Ce, Si, and Y. The coating can flatten the core neutron flux distribution, and realize long-term reactivity control and negative temperature coefficient control for moderator. The coating and the substrate have good compatibility from room temperature to 800° C. The relative density of the coating is between 70% and 97% (that is, the density of the burnable poison coating is 70% to 97% of the theoretical density of the used material). It should be noted that if the relative density of the coating is too low, a large number of connected pores will appear in the coating, resulting in a significant decrease in the geometric stability of the coating and the adhesion between the coating and the pellet, which is not conducive to ensuring the reliability of service in the reactor. If the relative density is too high, the physical vapor deposition efficiency is too low, and engineering production cannot be achieved, which increases the production cost. The thickness of the coating is between 1.5 and 20 mm, and the ¹⁰B linear density in the coating is 0.02 to 0.1 mg/mm.

### Example 1: Relationship Among Relative Density of Coating, ¹⁰B Enrichment and Thickness of Coating Under Different Line Densities of Coating

When the coating ¹⁰B linear density of the burnable poison coating is 0.02 mg/mm, the coatings are composed of SiB₆, YB₆ and CeB₆ respectively, and the relative densities of coatings are 70% and 97%, the thicknesses of coatings are shown in Table 1. When the coating is composed of a combination of two or three of SiB₆, YB₆ and CeB₆, and the relative densities of coatings are between 70% and 97%, the thicknesses of coatings are between 1.7 μm to 4.0 μm.

TABLE 1
relationship among relative density, ¹⁰B enrichment
and thickness of coating of burnable poison coatings
(¹⁰B linear density being 0.02 mg/mm)

| | Relative | ¹⁰B | Thickness |
|---|---|---|---|
| | density of | enrichment | of coating |
| Material composition | coating (%) | (wt %) | (μm) |
| SiB₆ | 70 | 18.4 | 4.0 |
| SiB₆ | 70 | 20 | 3.7 |
| SiB₆ | 70 | 25 | 3.0 |
| SiB₆ | 70 | 30 | 2.5 |
| YB₆ | 70 | 18.4 | 3.9 |
| YB₆ | 70 | 20 | 3.6 |
| YB₆ | 70 | 25 | 2.9 |
| YB₆ | 70 | 30 | 2.4 |
| CeB₆ | 70 | 18.4 | 4.0 |
| CeB₆ | 70 | 20 | 3.7 |
| CeB₆ | 70 | 25 | 2.9 |
| CeB₆ | 70 | 30 | 2.5 |
| SiB₆ | 97 | 18.4 | 2.9 |
| SiB₆ | 97 | 20 | 2.7 |
| SiB₆ | 97 | 25 | 2.1 |
| SiB₆ | 97 | 30 | 1.8 |
| YB₆ | 97 | 18.4 | 2.8 |
| YB₆ | 97 | 20 | 2.6 |
| YB₆ | 97 | 25 | 2.1 |
| YB₆ | 97 | 30 | 1.7 |
| CeB₆ | 97 | 18.4 | 2.9 |
| CeB₆ | 97 | 20 | 2.6 |
| CeB₆ | 97 | 25 | 2.1 |
| CeB₆ | 97 | 30 | 1.8 |
| 50 wt % SiB₆ + 50 wt % YB₆ | 70 | 18.4 | 4.0 |
| 50 wt % SiB₆ + 50 wt % CeB₆ | 70 | 18.4 | 4.0 |
| 50 wt % YB₆ + 50 wt % CeB₆ | 70 | 18.4 | 4.0 |

When the coating ¹⁰B linear density of the burnable poison coating is 0.10 mg/mm, the coatings are composed of SiB₆, YB₆ and CeB₆ respectively, and the relative densities of coatings are 70% and 97%, the thicknesses of coatings are shown in Table 2. When the composition of coating is composed of a combination of two or three of SiB₆, YB₆ and CeB₆, and the relative densities of coatings are between 70% and 97%, the thicknesses of coatings are 8.6 μm to 20 μm.

TABLE 2
relationship among relative density, ¹⁰B enrichment
and thickness of coating of burnable poison coatings
(¹⁰B linear density being 0.10 mg/mm)

| | Relative | ¹⁰B | Thickness |
|---|---|---|---|
| | density of | enrichment | of coating |
| Material composition | coating (%) | (wt %) | (μm) |
| SiB₆ | 70 | 18.4 | 20.0 |
| SiB₆ | 70 | 20 | 18.4 |
| SiB₆ | 70 | 25 | 14.7 |
| SiB₆ | 70 | 30 | 12.3 |
| YB₆ | 70 | 18.4 | 19.3 |
| YB₆ | 70 | 20 | 17.8 |
| YB₆ | 70 | 25 | 14.3 |
| YB₆ | 70 | 30 | 11.9 |
| CeB₆ | 70 | 18.4 | 19.8 |
| CeB₆ | 70 | 20 | 18.3 |
| CeB₆ | 70 | 25 | 14.7 |
| CeB₆ | 70 | 30 | 12.3 |
| SiB₆ | 97 | 18.4 | 14.4 |
| SiB₆ | 97 | 20 | 13.3 |
| SiB₆ | 97 | 25 | 10.6 |
| SiB₆ | 97 | 30 | 8.9 |
| YB₆ | 97 | 18.4 | 13.9 |
| YB₆ | 97 | 20 | 12.8 |
| YB₆ | 97 | 25 | 10.3 |
| YB₆ | 97 | 30 | 8.6 |
| CeB₆ | 97 | 18.4 | 14.3 |
| CeB₆ | 97 | 20 | 13.2 |
| CeB₆ | 97 | 25 | 10.6 |
| CeB₆ | 97 | 30 | 8.9 |
| 50 wt % YB₆ + 50 wt % CeB₆ | 70 | 18.4 | 19.7 |
| 50 wt % YB₆ + 50 wt % CeB₆ | 70 | 18.4 | 19.9 |
| 50 wt % YB₆ + 50 wt % CeB₆ | 70 | 18.4 | 19.6 |

When the coating ¹⁰B linear density of the burnable poison coating is 0.077 mg/mm, the coatings are composed of SiB₆, YB₆ and CeB₆ respectively, and the relative densities of coatings are 70% and 97%, the thicknesses of coatings are shown in Table 3. When the composition of coating is composed of a combination of two or three of SiB₆, YB₆ and CeB₆, and the relative densities of coatings are between 70% and 97%, the thicknesses of coatings are 6.6 μm to 15.4 μm.

TABLE 3
relationship among relative density, ¹⁰B enrichment
and thickness of coating of burnable poison coatings
(¹⁰B linear density being 0.077 mg/mm)

| | Relative | ¹⁰B | Thickness |
|---|---|---|---|
| | density of | enrichment | of coating |
| Material composition | coating (%) | (wt %) | (μm) |
| SiB₆ | 70 | 18.4 | 15.4 |
| SiB₆ | 70 | 20 | 14.2 |
| SiB₆ | 70 | 25 | 11.4 |
| SiB₆ | 70 | 30 | 9.5 |
| YB₆ | 70 | 18.4 | 14.8 |
| YB₆ | 70 | 20 | 13.7 |
| YB₆ | 70 | 25 | 11.0 |
| YB₆ | 70 | 30 | 9.2 |
| CeB₆ | 70 | 18.4 | 15.3 |
| CeB₆ | 70 | 20 | 14.1 |
| CeB₆ | 70 | 25 | 11.3 |
| CeB₆ | 70 | 30 | 9.5 |
| SiB₆ | 97 | 18.4 | 11.1 |
| SiB₆ | 97 | 20 | 10.2 |
| SiB₆ | 97 | 25 | 8.2 |
| SiB₆ | 97 | 30 | 6.9 |
| YB₆ | 97 | 18.4 | 10.7 |
| YB₆ | 97 | 20 | 9.9 |
| YB₆ | 97 | 25 | 7.9 |
| YB₆ | 97 | 30 | 6.6 |
| CeB₆ | 97 | 18.4 | 11.0 |
| CeB₆ | 97 | 20 | 10.2 |
| CeB₆ | 97 | 25 | 8.2 |
| CeB₆ | 97 | 30 | 6.8 |
| 50 wt % YB₆ + 50 wt % CeB₆ | 70 | 18.4 | 15.1 |
| 50 wt % YB₆ + 50 wt % CeB₆ | 70 | 18.4 | 15.4 |
| 50 wt % YB₆ + 50 wt % CeB₆ | 70 | 18.4 | 15.1 |

### Example 2: Comparison Between the Nuclear Properties of the Burnable Poison Coating According to the Present Application and the Commercial ZrB₂ Coating

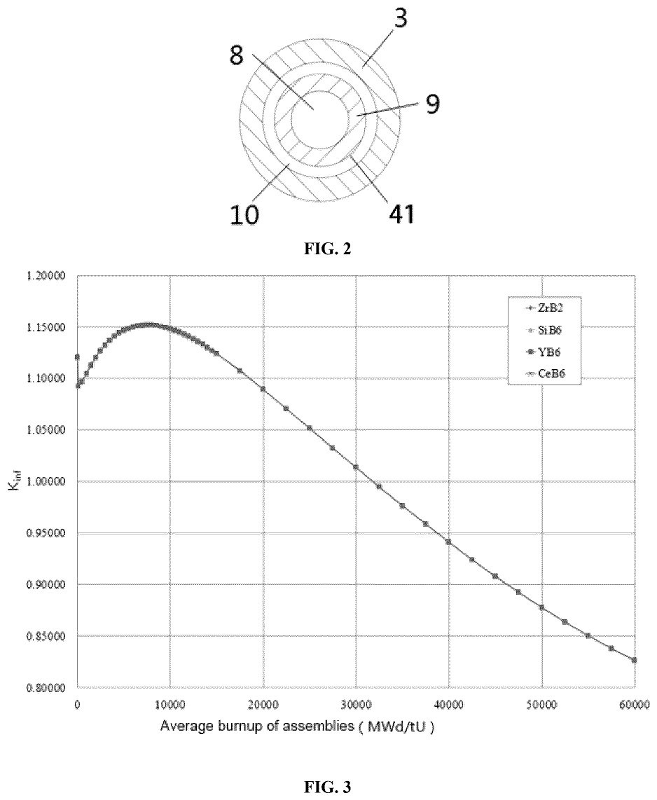

When the coating ¹⁰B linear density of the burnable poison coating is 0.077 mg/mm, the relative density of coating is 74%, and the coatings are composed of SiB₆, YB₆ and CeB₆ respectively, according to the relative density and thickness of the coatings provided in Table 4, the nuclear properties of the above-mentioned materials with natural abundance (¹⁰B abundance is 18.4 wt %) are basically equivalent to that of the commercial ZrB₂ coating. In this case, the ¹⁰B enrichment of the raw material of boric acid used for production is reduced from 24.4 wt % to natural abundance, which effectively reduces the cost of raw materials and has the same reactivity adjustment function. The nuclear property curves of the burnable poison coating of this example and of the ZrB₂ coating are shown in FIG. 3, which shows that the nuclear properties of the three schemes of new integral burnable poison absorber material are basically consistent with that of the scheme of the ZrB₂ coating. As shown in Table 7, based on the given design parameters, the neutron absorption capabilities of schemes of CeB₆, YB₆, and SiB₆ coatings at zero burnup are higher than that of the scheme of the ZrB₂ coating by about 166 pcm, 148 pcm, and 119 pcm, respectively. When comparing in the burnup range of 15000~60000 MWd/tU, the neutron reactivity penalties of the three materials are slightly higher than that of ZrB₂, and the reactivity penalties are sorted from high to low as CeB₆, YB₆, and SiB₆.

TABLE 4
parameters of burnable poison coatings with nuclear
properties equivalent to that of the commercial ZrB₂ coating
(¹⁰B being in natural enrichment)

| Material | Relative density | ¹⁰B enrichment | Thickness of |
|---|---|---|---|
| composition | of coating (%) | (wt %) | coating (μm) |
| ZrB₂ | 74 | 24.4 | 14.3 |
| CeB₆ | 74 | 18.4 | 14.5 |
| YB₆ | 74 | 18.4 | 14.1 |
| SiB₆ | 74 | 18.4 | 14.6 |

TABLE 5
parameters of burnable poison coatings with nuclear
properties equivalent to that of the commercial ZrB₂ coating
(¹⁰B being in 20% enrichment)

| Material | Relative density | ¹⁰B enrichment | Thickness |
|---|---|---|---|
| composition | of coating (%) | (wt %) | of coating |
| ZrB₂ | 74 | 26.5 | 13.2 |
| CeB₆ | 74 | 20 | 13.3 |
| YB₆ | 74 | 20 | 13.0 |
| SiB₆ | 74 | 20 | 13.4 |

TABLE 6
parameters of burnable poison coatings with nuclear
properties equivalent to that of the commercial ZrB₂ coating
(¹⁰B being in 25% enrichment)

| Material | Relative density | ¹⁰B enrichment | Thickness |
|---|---|---|---|
| composition | of coating (%) | (wt %) | of coating |
| ZrB₂ | 74 | 33 | 10.6 |
| CeB₆ | 74 | 25 | 10.7 |
| YB₆ | 74 | 25 | 10.4 |
| SiB₆ | 74 | 25 | 10.8 |

TABLE 7
reactivity differences between each of the three burnable
poison absorbent materials and the commercial ZrB₂

| Assembly | Reactivity difference relative to the | | |
|---|---|---|---|
| burnup | ZrB₂ material (pcm) | | |
| (MWd/tU) | SiB₆ | YB₆ | CeB₆ |
| 0 | −119 | −148 | −166 |
| 100 | −130 | −131 | −80 |
| 1000 | −72 | −52 | 11 |
| 2000 | −8 | −14 | −7 |
| 3000 | −61 | −52 | −56 |
| 4000 | −75 | −52 | −42 |
| 5000 | −63 | −63 | −12 |
| 6000 | −77 | −95 | −32 |
| 7000 | −116 | −106 | −26 |
| 8000 | −35 | −22 | −40 |
| 9000 | −43 | −79 | −25 |
| 10000 | −38 | −4 | 7 |
| 11000 | −73 | −10 | 1 |
| 12000 | −67 | −41 | −13 |
| 13000 | −26 | −11 | −18 |
| 14000 | −53 | −35 | −42 |
| 15000 | −2 | 14 | −22 |
| 17500 | −55 | −20 | 32 |
| 20000 | 33 | 18 | −2 |
| 22500 | −16 | −15 | −1 |
| 25000 | 26 | 21 | 57 |
| 27500 | 38 | 36 | 52 |
| 30000 | −15 | 17 | 5 |
| 32500 | −32 | 3 | −26 |
| 35000 | −86 | −7 | −16 |
| 37500 | 54 | 98 | 98 |
| 40000 | −43 | 14 | −2 |
| 42500 | −43 | −32 | −29 |
| 45000 | −74 | −21 | −45 |
| 47500 | −38 | 36 | −3 |
| 50000 | −54 | −1 | 27 |
| 52500 | −18 | −31 | −27 |
| 55000 | 0 | −13 | 18 |
| 57500 | −47 | 2 | 21 |

It can be clearly seen from the data in example 2 that the burnable poison coating according to the present application implements the same functions of reactivity control and negative temperature coefficient control for moderator as that of the commercial ZrB₂, and the initial reactivity value of the coating is basically the same as that of the ZrB₂ coating with the same ¹⁰B linear density; and the reactivity penalty at the end of life of the coating is basically the same as that of the ZrB₂ coating with the same ¹⁰B linear density, but the requirement for the ¹⁰B enrichment can be reduced, thereby effectively reducing the cost of raw materials.

### Example 3: Application of the CeB₆ Coating on UO₂ Pellets by Magnetron Sputtering

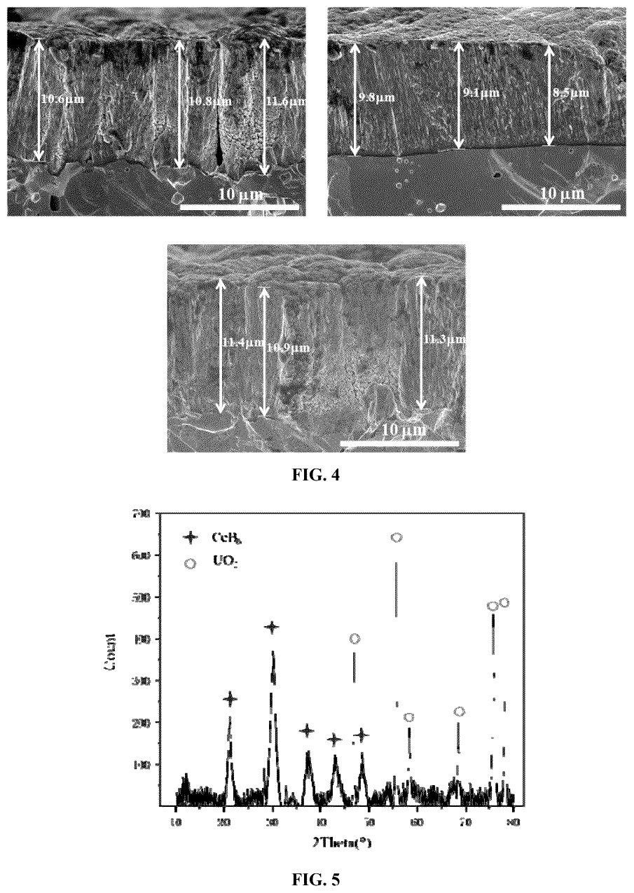

The CeB₆ coating on the outer surface of the fuel pellet is prepared by a magnetron sputtering apparatus equipped with a radio frequency power supply, and a CeB₆ target material with a diameter of 50 mm is adopted. A cylindrical UO₂ fuel pellet is placed at the center of the bottom plate of the rotating sample holder, and the upper surface of the sample is covered with a metal sheet to avoid being contaminated by the coating. The Ar gas flow rate is adjusted to 60 sccm, the vacuum is 0.6 Pa, and the temperature in the sample chamber is maintained at 200° C. After the arcing of the magnetron, the sample is coated while the current of the CeB₆ target material is maintained at 120 mA. After coating for 60 hours, the temperature in the sample chamber is raised to 400° C. and held for 1 h. Through observation by SEM, the microstructure of the cross section of the coated pellet is shown in FIG. 4, and the average film thickness is about 10 μm. The grazing incident X-ray diffraction spectrum of the coated surface of the pellet is shown in FIG. 5. From the X-ray diffraction spectrum, it can be seen that besides the diffraction peak of the UO₂ substrate, the rest are the diffraction peaks of CeB₆, proving that the CeB₆ coating has a high purity. The above examples show that the burnable poison coating according to the present application has manufacturing feasibility and the coating has a high degree of crystallization. It should be noted that the thickness of coating can be regulated by adjusting the preparation process parameters and the test implementation time.

TABLE 8
parameters of every round of coating magnetron sputtering process

| Vacuum degree | 5 × 10⁻⁴ | Pa |
|---|---|---|
| Sputtering power of | 100 | W |
| target material | | |
| Flow rate of Argon | 60 | sccm |
| Partial pressure of Argon | 1.0 | Pa |
| Rotation speed of | 1 | rpm |
| Substrate | | |
| Target-substrate distance | 60 | mm |
| Sputtering mode | RF sputtering, no negative bias | |
| Heating temperature | 400° | C. |

| | |
|---|---|
| Cycle Mode | After the substrate is rotated and sputtered |
| | for 8 h~10 h, the temperature is raised to |
| | 400° C. and held for 1 h, then the temperature |
| | is lowered, and the transfer to the next |
| | coating cycle is performed |

### Example 4: Comparison of Peel Test Results Between the UO₂ Pellet Coated with CeB₆ and the UO₂ Pellet Coated with ZrB₂

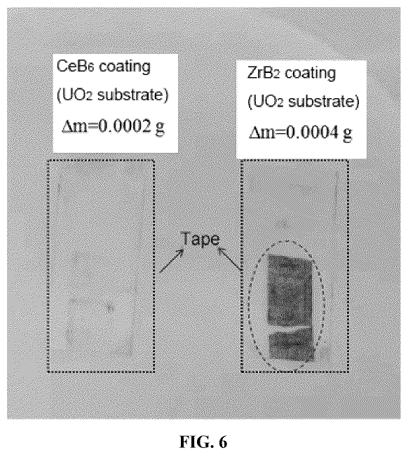

A calibrated tape is used to perform a peel test on the UO₂ pellet coated with CeB₆ (relative density of 90%, natural enrichment, thickness of 10 μm). After 600° C. thermal shock tests for at least 3 times, the result for the CeB₆ coating is shown on the left and the result for the ZrB₂ coating is shown on the right. The adhesion between the CeB₆ coating and the UO₂ substrate is good, and after multiple thermal shocks, the mass peeled off by tape is 0.0002 g, which is lower than the mass loss of the ZrB₂ coating (0.0004 g). The tape photo captured after peeling is shown in FIG. 6. After the peel test of the UO₂ pellet coated with CeB₆, no obvious peeled off material is found on the tape, while after the peel test of the UO₂ pellet coated with ZrB₂, obvious peeled off material is found on the tape (shown in the circle in FIG. 6). The above examples show that the burnable poison coating according to the present application is tightly bonded to the fuel pellet substrate, which is better than the UO₂ pellet coated with ZrB₂.

Compared with CN111573687A, the main difference of this application is that: three material schemes of SiB₆, YB₆ and CeB₆ are preferably selected, and uniform coating on the surface of nuclear fuel pellets is achieved through the magnetron sputtering process, which provides a specific application scenario of coating on fuel pellets and integrating into fuel elements. The burnable poison coating according to this invention achieves the purpose of using lower ¹⁰B abundance or even natural abundance materials to equivalently replace high abundance ZrB₂ coating in terms of reactivity regulation function, while having advantages in raw material cost and bonding strength between coating and substrate.

The above are only preferred embodiments of the present application, and are not intended to limit the present application. For those skilled in the art, the present application may have various modifications and changes. Any modifications, equivalent replacements, improvements, etc. made within the spirit and principles of the present application shall be included within the protection scope of this application.

1. A burnable poison coating, wherein
the burnable poison coating is made of at least one of CeB₆, SiB₆, and YB₆, and a relative density of the burnable poison coating is 70% to 97% of a theoretical density of used material.

2. The burnable poison coating according to claim 1, wherein the burnable poison coating has a thickness of 5 to 20 μm.

3. The burnable poison coating according to claim 1, wherein the burnable poison coating has a ¹⁰B linear density of 0.02 to 0.1 mg/mm.

4. The burnable poison coating according to claim 1, wherein
a ¹⁰B enrichment in the burnable poison coating is 18.4 wt % to 30 wt %.

5. The burnable poison coating according to claim 1, wherein an initial reactivity value of the burnable poison coating differs by no more than 200 pcm from that of a ZrB₂ coating with the same ¹⁰B linear density; or
a reactivity penalty at end of life of the burnable poison coating differs by no more than 30 pcm from that of the ZrB₂ coating with the same ¹⁰B linear density; or
after being subjected to 600° C. thermal shock tests for at least 3 times, the burnable poison coating has a mass loss of less than 0.0006 g as measured by a tape peel test.

6. A method for preparing the burnable poison coating according to claim 1, wherein the burnable poison coating is prepared by a magnetron sputtering process, and a specific operation process of the method comprises:
adopting a coating material composed of at least one of CeB₆, SiB₆, and YB₆, placing a fuel pellet at center of a bottom plate of a rotating sample holder in a sample chamber, and covering an upper surface of a sample with a metal sheet; and
adjusting an Ar gas flow rate in the sample chamber into a range of 60 to 80 sccm, adjusting a vacuum degree in the sample chamber into a range of 0.6 to 0.8 Pa, maintaining a temperature in the sample chamber in a range of 200 to 300° C., coating the fuel pellet for 60 to 70 hours while maintaining a current of the coating material in a range of 120 to 150 mA after arcing of a magnetron, and raising temperature in the sample chamber to a range of 400 to 420° C. which is then maintained for 1 to 1.2 h.

7. A nuclear fuel element comprising a nuclear fuel pellet, wherein a surface of the nuclear fuel pellet is coated with the burnable poison coating according to claim 1.

8. The nuclear fuel element according to claim 7, wherein a material of the nuclear fuel pellet is at least one of uranium dioxide, thorium dioxide, plutonium dioxide, uranium dioxide-gadolinium oxide, thorium dioxide-gadolinium oxide, plutonium dioxide-gadolinium oxide and mixtures thereof.

9. The nuclear fuel element according to claim 7, further comprising a structural material for isolating the nuclear fuel pellet from a coolant and a sealing material for blocking an opening of the structural material, wherein the structural material and the sealing material have thermal neutron microscopic absorption cross sections not exceeding 1.5 barns, and no apparent chemical reaction occurs with the nuclear fuel pellet and the coolant in a range of room temperature to 800° C.

10. The method for preparing the burnable poison coating according to claim 6, wherein the burnable poison coating has a thickness of 5 to 20 μm.

11. The method for preparing the burnable poison coating according to claim 6, wherein the burnable poison coating has a ¹⁰B linear density of 0.02 to 0.1 mg/mm.

12. The method for preparing the burnable poison coating according to claim 6, wherein a ¹⁰B enrichment in the burnable poison coating is 18.4 wt % to 30 wt %.

13. The nuclear fuel element according to claim 7, wherein the burnable poison coating has a thickness of 5 to 20 μm.

14. The nuclear fuel element according to claim 7, wherein the burnable poison coating has a ¹⁰B linear density of 0.02 to 0.1 mg/mm.

15. The nuclear fuel element according to claim 7, wherein a ¹⁰B enrichment in the burnable poison coating is 18.4 wt % to 30 wt %.

16. The nuclear fuel element according to claim 7, wherein an initial reactivity value of the burnable poison coating differs by no more than 200 pcm from that of a ZrB₂ coating with the same ¹⁰B linear density; or
a reactivity penalty at end of life of the burnable poison coating differs by no more than 30 pcm from that of the ZrB₂ coating with the same ¹⁰B linear density; or
after being subjected to 600° C. thermal shock tests for at least 3 times, the burnable poison coating has a mass loss of less than 0.0006 g as measured by a tape peel test.
